(19) United States
(12) Patent Application Publication
(10) Pub. No.: US 2017/0210036 A1
(43) Pub. Date: Jul. 27, 2017

(54) MOLD REPLICATING METHOD, IMPRINT APPARATUS, AND ARTICLE MANUFACTURING METHOD

(71) Applicant: CANON KABUSHIKI KAISHA, TOKYO (JP)

(72) Inventors: Zenichi Hamaya, Utsunomiya-shi (JP); Tatsuya Hayashi, Utsunomiya-shi (JP)

(21) Appl. No.: 15/410,871

(22) Filed: Jan. 20, 2017

(30) Foreign Application Priority Data
Jan. 22, 2016 (JP) 2016-010534
Dec. 22, 2016 (JP) 2016-249830

(51) Int. Cl. B29C 33/38; G03F 7/00

(52) U.S. Cl. CPC B29C 33/3842; G03F 7/0002; B29K 2909/08; B29K 2905/08; B29K 2905/14

(57) ABSTRACT

A mold replicating method for replicating a master mold (mold) by forming a pattern of the master mold on a substrate, the method comprising: obtaining information related to a shape difference between a pattern region of the master mold and a pattern region of the substrate; and deforming a relative shape of the pattern region of the master mold and the pattern region of the substrate by applying heat based on the information. The master mold (mold) and the substrate differ in an amount of deformation with respect to the heat applied.

### BACKGROUND OF THE INVENTION

Field of the Invention

The present invention relates to a mold replicating method, an imprint apparatus, and an article manufacturing method.

Description of the Related Art

An imprint technique is a fine processing technique that forms a pattern of a fine structure in an imprint material (uncured resin) on a substrate by using a mold. One of the imprint techniques is a photocuring method. In an imprint apparatus that employs this photocuring method, first, the imprint material that is cured by a light that has been irradiated, such as ultraviolet rays, is applied to a shot region, which is an imprint region on the substrate. Next, this imprint material is shaped by the mold. Subsequently, ultraviolet rays are irradiated in a state in which the imprint material and the mold are in contact, the imprint material is cured, the mold is released from the imprint material that has been cured, and consequently, a pattern of the imprint material is formed on the substrate.

In order to irradiate ultraviolet rays to the imprint material on the substrate, quartz having a high transmittance of ultraviolet rays is used to serve as a mold. A fine structure of several to several tens of nanometer order is formed on a pattern surface of the mold. Since the imprint repeatedly contacts the mold and the imprint material, if the mold is degraded or if foreign matters is interposed between the mold and the substrate, the fine structure formed in the mold may physically be damaged. The mold is a consumable item, and then it needs to be replaced with a new one in a case that the mold is damaged or before the mold is damaged. Since the fine structure in the mold is produced by an electron beam drawing apparatus and through a developing process, the productivity is low and the cost is high.

Accordingly, the mold that was produced by the electron beam drawing apparatus serves as a master mold, and the replication of the mold (replica mold) is produced by using the above imprint techniques. This replication by the imprint techniques enables to greatly improve the productivity and cost of the mold. Upon replicating the mold, it is important to correctly transfer the fine structure of the mold (master mold) that has been produced by the electron beam drawing apparatus to the quartz substrate. However, when a strain occurs on the mold or the quartz substrate, the pattern of the mold may be transferred to the quartz substrate after the mold has been distorted. The manufacture of a semiconductor device by using the replica mold with a distorted pattern cannot avoid the reduction of the accuracy of superimposition. Japanese Patent Application Laid-Open Publication No. 2012-89636 discloses an imprint method that corrects distortion by adding a force to the master mold and accordingly corrects the misalignment (mold replicating method) during the produce of the replica mold by imprint.

There is a technique that further corrects the distortion that cannot be corrected only by the correction by a force, by using heat. However, both the master mold and the replica mold disclosed in Japanese Patent Application Laid-Open Publication No. 2012-89636 are made of quartz, and the thermal expansion coefficients are the same level. In a case where the thermal expansion coefficients of the mold and the substrate are the same, when the mold contacts the imprint material on the substrate and heat input is provided, the heat of the mold is transmitted to the substrate, and the both of the mold and the substrate become the same temperature. As a result, an amount of relative deformation between the mold and the substrate by using heat cannot be obtained, and it is difficult to correct a pattern shape to be formed onto the substrate by using heat.

### SUMMARY OF THE INVENTION

The present invention provides, for example, a mold replicating method that can replicate a mold with a high accuracy.

The present invention is a mold replicating method for replicating a master mold by forming a pattern of the master mold on a substrate, the method comprising steps of: obtaining information related to a shape difference between a pattern region of the master mold and a pattern region of the substrate; and deforming a relative shape of the pattern region of the master mold and the pattern region of the substrate by applying heat based on the information, wherein the master mold and the substrate differ in an amount of deformation with respect to heat that has been applied.

Further features of the present invention will become apparent from the following description of exemplary embodiments with reference to the attached drawings.

### BRIEF DESCRIPTION OF THE DRAWINGS

FIG. 1 illustrates a configuration of an imprint apparatus.

FIG. 2 is a flowchart illustrating an imprint process.

FIG. 3 illustrates a configuration of a mold shape correction mechanism.

FIGS. 4A to 4D illustrate a correction method for a mold and a substrate.

FIG. 5 illustrates the mold and the substrate viewed from a side view.

### DESCRIPTION OF THE EMBODIMENTS

### First Embodiment

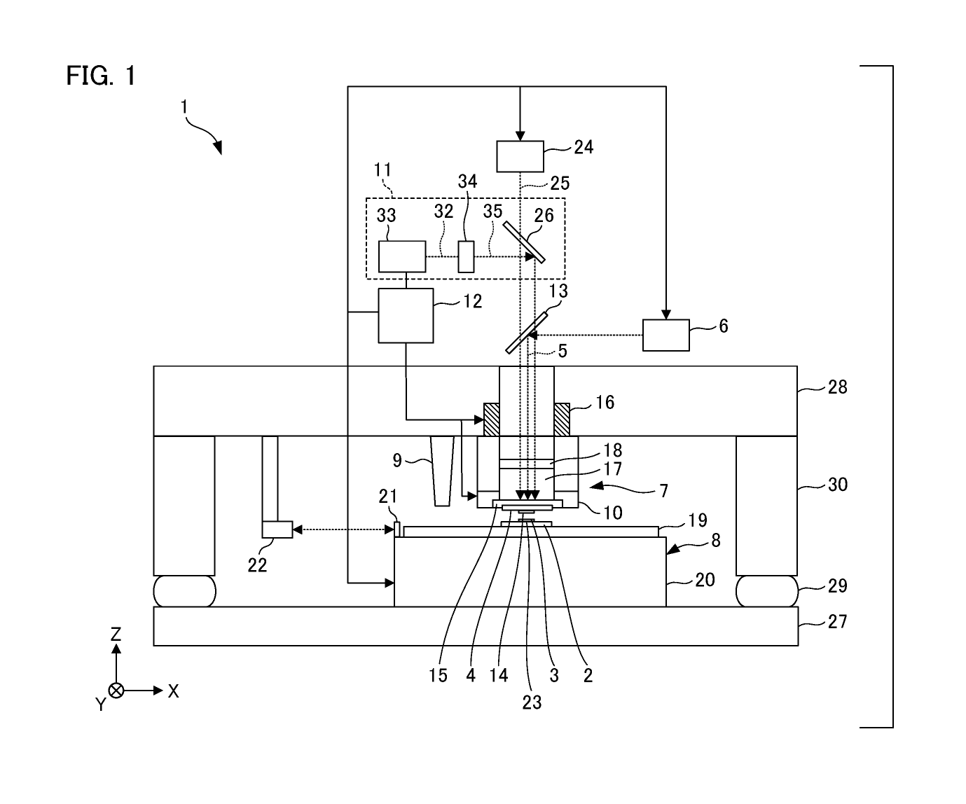

FIG. 1 illustrates a configuration of an imprint apparatus 1 according to the present embodiment. The imprint apparatus is an apparatus that forms a pattern of a cured product onto which a convex-concave pattern of a mold has been transferred by contacting an imprint material supplied onto a substrate with the mold and supplying energy for curing to the imprint material. This imprint apparatus 1 is used in the manufacture of a semiconductor device serving as an article and used in the replication of the mold, shapes an imprint material 3 (uncured resin) applied to a substrate 2 serving as a substrate to be processed by a mold 4, and forms a pattern on the substrate 2. In the present embodiment, a replica mold that is a replication of the master mold (original mold) is produced by transferring a pattern of the mold onto the substrate, where the master mold serves as the mold, by using the imprint apparatus 1. Note that an example of the imprint apparatus 1 employing the light curing method will be described herein. Additionally, in each of drawings described below, the Z-axis is taken in parallel with the optical axis of ultraviolet rays 5 that are incident to the imprint material 3 on the substrate 2, and the X-axis and the Y-axis orthogonal each other are taken in a plane perpendicular to the Z-axis.

The imprint apparatus 1 first comprises a light irradiation unit 6, a mold holding mechanism 7, a substrate stage 8, a applying unit 9, a mold shape correction mechanism 10, a substrate heating mechanism 11, and a control unit 12. The light irradiation unit 6 irradiates the ultraviolet rays 5 to the mold 4 and the substrate 2 in the imprint process. This light irradiation unit 6 is configured by a light source (not illustrated) and an optical element (not illustrated) that adjusts the ultraviolet rays 5 irradiated from this light source to a suitable light for the imprint. The ultraviolet rays 5 that have been irradiated are reflected by a dichroic mirror 13 and are guided to the mold 4 and the substrate 2.

The mold 4 has a rectangular outer peripheral shape and includes a pattern portion 14 that is a pattern region of the master mold in which a convex-concave pattern to be transferred, for example, a circuit pattern is formed in a three-dimensional shape, in a surface facing the substrate 2. Additionally, a material that can transmit the ultraviolet rays 5 is used as the material of the mold 4. Moreover, the mold 4 may have a shape in which a cavity (concave portion) having a circular planar shape and a certain depth is formed on a surface to which the ultraviolet rays 5 are irradiated, in order to facilitate the deformation of the pattern portion 14 by the mold shape correction mechanism 10 described below.

The mold holding mechanism 7 first has a mold holding unit 15 that holds the mold 4, and a mold drive mechanism 16 that holds this mold holding unit 15 and moves the mold 4. The mold holding unit 15 can hold the mold 4 by using a vacuum suction force or an electrostatic force to attract a peripheral region of the irradiation surface of the ultraviolet rays 5 in the mold 4. For example, if the mold holding unit 15 holds the mold 4 by a vacuum suction force, the mold holding unit 15 is connected to a vacuum pump (not illustrated) disposed outside, the attachment and detachment of the mold 4 is switched by turning this vacuum pump ON and OFF. Additionally, the mold holding unit 15 and the mold drive mechanism 16 have an opening region 17 in the center (inner side) such that the ultraviolet rays 5 irradiated from the light irradiation unit 6 are directed toward the substrate 2. In this opening region 17, a configuration may be used in which a light transmission member 18 (for example, a quartz plate), which serves a space surrounded by a part of the opening region 17 and the mold 4 as an enclosed space, is disposed, and a space pressure in the opening region 17 can be adjusted by a pressure adjustment device (not illustrated). The pressure adjustment device, for example, sets the pressure in the space higher than that in the outside of the space upon contacting the mold 4 with the imprint material 3 on the substrate 2, and thus makes the pattern portion 14 deflect in a convex shape toward the substrate 2, and can contact the imprint material 3 to the pattern portion 14 from the center. Accordingly, it is possible to suppress the remaining gas between the pattern portion 14 and the imprint material 3, and to fill the imprint material 3 throughout the convex-concave portion of the pattern portion 14. Additionally, instead of convexly deflecting the pattern portion 14 toward the substrate 2, it may be possible to convexly deflect a surface applied to the imprint material 3 on the substrate 2 toward the pattern portion 14 and make the mold 4 in contact with the imprint material 3 on the substrate 2.

The mold drive mechanism 16 moves the mold 4 in each axis direction so as to selectively perform the contacting (mold contacting) or the releasing (mold releasing) of the mold 4 and the imprint material 3 on the substrate 2. As an actuator that can be adopted to this mold drive mechanism 16 such as a voice coil motor, an air cylinder, and the like are used. Additionally, in order to be compatible with the high-accuracy positioning of the mold 4, the mold drive mechanism 16 may be configured by a plurality of drive systems, such as a coarse drive system and a fine drive system. Furthermore, the mold drive mechanism 16 may have a configuration having a position adjusting function in the X-axis direction, the Y-axis direction, or the θ-axis (rotation around the Z-axis) direction, in addition to the Z-axis direction, and a tilt function for correcting the tilt of the mold 4. Note that the contacting operation or the releasing operation of the pattern portion 14 in the imprint apparatus 1 may be realized by moving the mold 4 in the Z-axis direction, but it may be realized by moving the substrate stage 8 in the Z-axis direction, or it may be realized by relatively moving the both.

The imprint material 3 shaped by the pattern portion 14 is applied to a surface to be processed of the substrate 2 by the applying unit 9. The substrate stage 8 holds the substrate 2 and performs the positioning of the mold 4 and the substrate 2 for contacting the mold 4 and the imprint material 3 on the substrate 2. This substrate stage 8 has a substrate holding unit 19 that holds the substrate 2 by a vacuum suction force or an electrostatic force, and a stage drive mechanism 20 that holds this substrate holding unit 19 by a mechanical means and is movable in each axis direction. As an actuator that is employable to this stage drive mechanism 20, for example, a linear motor or a planar pulse motor is used. The stage drive mechanism 20 may also be configured by a plurality of drive systems, such as a coarse drive system and a fine drive system, with respect to each direction of the X-axis and the Y-axis. Furthermore, the stage drive mechanism 20 may be configured to have a drive system for the position adjustment in the Z-axis direction, a position adjustment function in the θ-direction of the substrate 2, or a tilt function for correcting the tilt of the substrate 2. In addition, the substrate stage 8 comprises a plurality of reference mirrors 21 provided on the side surfaces thereof, which corresponds to each of the X, Y, Z, ωx, ωy, and ωz directions. In contrast, the imprint apparatus 1 comprises a plurality of laser interferometers 22 that measures the position of the substrate stage 8 by irradiating beams to these reference mirrors 21. The laser interferometer 22, which serves as a measuring unit, measures the position of the substrate stage 8, and the control unit 12, to be described below, executes a positioning control of the substrate 2 (substrate stage 8) based on the measurement value at this time.

The applying unit 9 (dispenser) is disposed near the mold holding unit 15, and applies (supplies) the imprint material 3 (uncured resin) onto the substrate 2. Here, this imprint material 3 is a photocurable resin (resist material) having the property of being curable by receiving the ultraviolet rays 5, and the kind of the imprint material 3 is appropriately selected depending on various conditions such as a semiconductor device manufacturing process or the like. As the imprint material 3, a curable composition that is cured by providing energy for curing (sometimes referred to as “uncured resin”) is used. As the energy for curing, electromagnetic waves, heat, or the like are used. As the electromagnetic waves, for example, a light such as infrared rays, a visible light, ultraviolet rays, the wavelength of which is selected from a range equal to or more than 10 nm or equal to or less than 1 mm, is used. The curable composition is a composition that is cured by irradiation of light or radiation, or by heat. Among these, the photocurable composition that is cured by a light may contain at least a polymerizable compound and a photopolymerization initiator, and may contain a non-polymerizable compound or a solvent as required. The non-polymerizable compound is at least one type selected from the group of, for example, a sensitizer, a hydrogen donor, an internal release agent, a surfactant, an antioxidant, and a polymer component. The imprint material is applied onto the substrate 2 in a film shape by a spin coater or a slit coater. Alternatively, it may be applied onto the substrate in a droplet shape, or an island shape or a film shape made by connecting a plurality of droplets, by a liquid jet head. The viscosity of the imprint material (the viscosity at 25° C.) is, for example, equal to or more than 1 mPa·s, and equal to or less than 100 mPa·s. Additionally, an amount of the imprint material 3 discharged from the applying unit 9 is also appropriately determined based on the desired thickness of the imprint material 3 formed on the substrate 2 and the density of the pattern to be formed.

For the imprint process, the imprint apparatus 1 comprises an alignment measuring unit 24 for obtaining the position information of a pattern formation region 23 that is a pattern region on the substrate 2, which becomes a portion to be processed. An alignment light 25 irradiated from the alignment measuring unit 24 is transmitted through the dichroic mirrors 26 and 13, and is irradiated to alignment marks (not illustrated) formed on the substrate 2. The alignment light 25 reflected at these alignment marks is received by the alignment measuring unit 24, and then the position information of the substrate 2 can be obtained.

The substrate heating mechanism 11 includes a heating source 33 that irradiates an irradiation light 32, a light adjustment device 34 that adjusts an amount of irradiation of this irradiation light 32, and a dichroic mirror 26 that regulates an optical path such that an adjusted light 35 that has been adjusted by the light adjustment device 34 is directed toward the surface of the substrate 2. The control unit 12 can control the operation and adjustment of each component included in the imprint apparatus 1. The control unit 12 is configured by, for example, a computer, connected to each component of the imprint apparatus 1 via a line, and can execute the control of each component in accordance with a program and the like. The control unit 12 of the present embodiment controls the operation of at least the mold holding unit 15, the substrate stage 8, the mold shape correction mechanism 10, the light irradiation unit 6, and the alignment measuring unit 24. Note that the control unit 12 may integrally be configured with the imprint apparatus 1 (in a shared housing), or may be configured separately from the imprint apparatus 1 (in a different housing).

Additionally, the imprint apparatus 1 comprises a base plate 27 on which the substrate stage 8 is mounted, a bridge plate 28 that supports the mold holding mechanism 7, and a column 30 that extends from the base plate 27 and supports the bridge plate 28 through a vibration isolating device 29. The vibration isolating device 29 removes the vibration transmitted from the floor to the bridge plate 28. Moreover, the imprint apparatus 1 may include, for example, a mold conveying mechanism (not illustrated) that conveys the mold 4 from the outside of the apparatus to the mold holding unit 15, and a substrate conveying mechanism (not illustrated) that conveys the substrate 2 from the outside of the apparatus to the substrate stage 8.

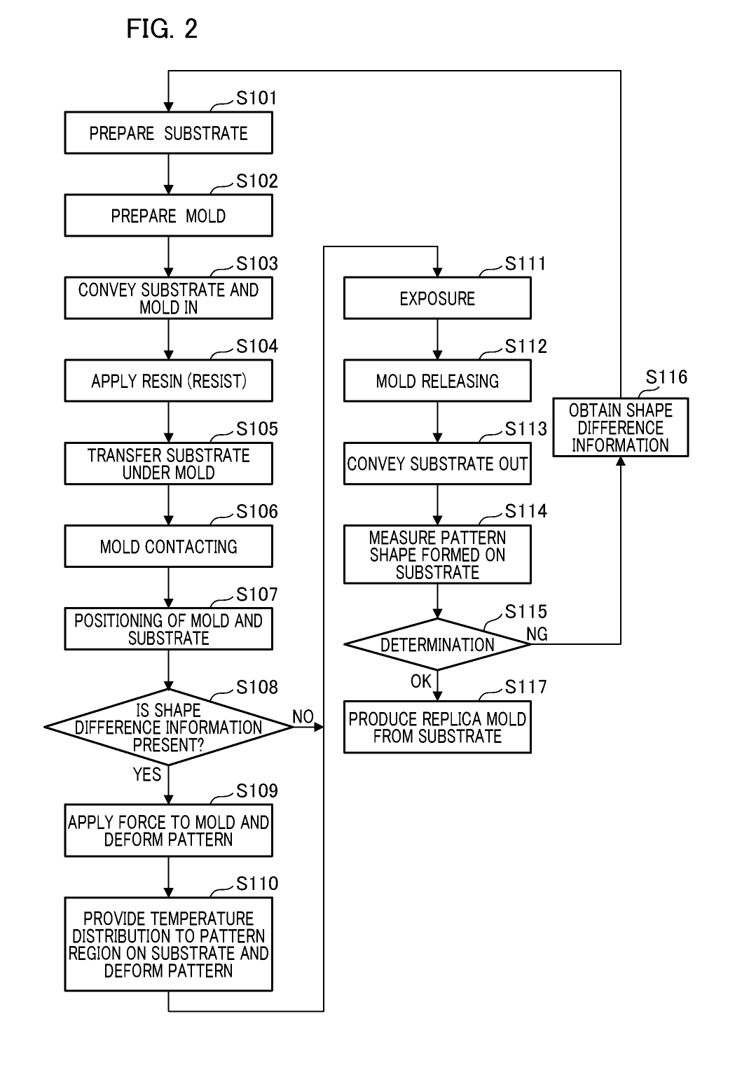

Next, the imprint process performed by the imprint apparatus 1 will be described with reference to FIG. 2. First, in step S101, the substrate 2 is prepared, and in step S102, the mold 4 is prepared. Conventionally, the material of the mold 4 needs to be a material that can transmit ultraviolet rays 5, and as an example, quartz is used. If a replica mold is produced from the master mold, the same quartz is used for the material since the substrate 2 is for producing a replication of the mold 4. However, in the present embodiment, the materials of the substrate 2 and the mold 4 are selected such that the heat expansion coefficients are different from each other. The details will be described below.

In step S103, the control unit 12 causes a substrate conveying mechanism (not illustrated) to convey the substrate 2 in the imprint apparatus 1, and causes the substrate 2 to be mounted and fixed to the substrate holding unit 19 on the substrate stage 8. The control unit 12 causes the mold conveying mechanism to convey the mold 4 in the imprint apparatus in a similar manner and causes the mold 4 to be fixed to the mold holding unit 15. In step S104, the control unit 12 causes the stage drive mechanism 20 to drive, to convey the pattern formation region 23 on the substrate 2 so as to be located directly under the applying unit 9, and performs the application of the imprint material 3. Subsequently, in step S105, the substrate 2 is conveyed directly under the mold 4 by the stage drive mechanism 20.

In step S106, the control unit 12 causes the mold drive mechanism 16 to drive as a mold contacting process, and brings the imprint material 3 on the substrate 2 and the pattern portion 14 into contact. By this mold contacting process, the imprint material 3 is filled into the convex-concave portion of the pattern portion 14. In step S107, the positioning of the mold 4 and the substrate 2 is performed. The control unit 12 causes the alignment measuring unit 24 to detect the alignment marks on the substrate 2, and detect the position of the pattern formation region 23. Based on the detected position information of the substrate 2, the control unit 12 calculates the shift and the rotation component of the substrate 2 with respect to the mold 4, and executes the positioning of the mold 4 and the substrate 2 by using the stage drive mechanism 20.

In step S108, in order to perform the shape correction of the pattern portion 14 and the pattern on the substrate 2, the control unit 12 determines whether or not the shape difference information is present. There is a case in which the shape difference information is not obtained immediately after the start of production of the replica mold by using the substrate 2, and thus it is not necessary to perform the correction by the mold shape correction mechanism 10 and the substrate heating mechanism 11. In step S108, if it is determined that the shape difference information is not present, the process proceeds to step S111. In contrast, once a pattern is formed on the substrate 2, it is possible to obtain the shape difference information from the pattern portion 14. If the pattern is present, the pattern shape formed on the substrate 2 can be corrected by the mold shape correction mechanism 10 and the substrate heating mechanism 11 by using the shape difference information for this pattern.

In step S108, if it is determined that the shape difference information is present, the process proceeds to step S109. In step S109, the mold shape correction mechanism 10 applies a force to the mold 4 based on the shape difference information of the pattern to deform the pattern portion 14. Next, in step S110, the substrate heating mechanism 11 forms an irradiation amount distribution (illuminance distribution) in the irradiation light 32 based on the shape difference information of the pattern, to provide a temperature distribution in the pattern on the substrate 2 by irradiating a light to the substrate 2 and thermally deform the pattern on the substrate 2. As a result, it is possible to transfer the pattern portion 14 onto the substrate 2 with a high accuracy. A detailed description will be given below regarding the shape correction by the mold shape correction mechanism 10 and the substrate heating mechanism 11. The deformation of the pattern portion 14 in step S109 and the deformation of the pattern on the substrate 2 in step S110 are not limited to being performed sequentially, and they may be performed simultaneously, or either one may be performed.

If the positioning of the mold 4 and the substrate 2, or the shape correction thereof, has been completed as required, in step S111, the control unit 12 causes the ultraviolet rays 5 to be irradiated from the light irradiation unit 6, and the imprint material 3 is cured by the ultraviolet rays 5 that have been transmitted through the mold 4. After the imprint material 3 is cured, in step S112, the control unit 12 causes the mold drive mechanism 16 to drive and executes the releasing process that releases the mold 4 from the imprint material 3. Accordingly, in the pattern formation region 23 on the substrate 2, the pattern of the imprint material 3 having a three-dimensional shape conforming to the convex-concave portion of the pattern portion 14 is formed. Subsequently, in step S113, the control unit 12 causes the substrate stage 8 to drive, and the substrate 2 is conveyed to the outside of the imprint apparatus 1.

The etching process is performed to the substrate 2 on which the pattern was formed, and the convex-concave pattern of the quartz is accordingly formed on the substrate 2. Subsequently, in step S114, the shape and the line width of the convex-concave pattern on the substrate 2 after forming the pattern is measured by a pattern inspection device (not illustrated). Based on the measurement result in step S114, the control unit 12 or an information processing device (not illustrated) disposed outside of the imprint apparatus 1 calculates the shape difference information between the shape of the pattern portion 14 and the pattern formed on the substrate 2.

In step S115, the control unit 12 or the information processing device (not illustrated) disposed outside of the imprint apparatus 1 determines whether or not the shape difference that has been calculated falls within standard values. If it is determined that the shape difference that has been calculated is within the standard values (OK), the process proceeds to step S117, the mass production of the substrate 2 starts under the current imprint condition, and the replica molds are produced based on the substrate 2. In contrast, in step S115, if it is determined that the shape difference that has been calculated is outside of the standard values (NG), the process proceeds to step S116, and based on the the shape difference information between the shape of the pattern portion 14 and the pattern formed on the substrate 2, the correction amount to be corrected by using the mold shape correction mechanism 10 and the substrate heating mechanism 11 is modified, and the modified correction amount is input to the control unit 12. As noted above, the imprint processes from step S101 to step S116 are repeated until the shape difference between the pattern portion 14 and the pattern formed on the substrate 2 falls within the standard values.

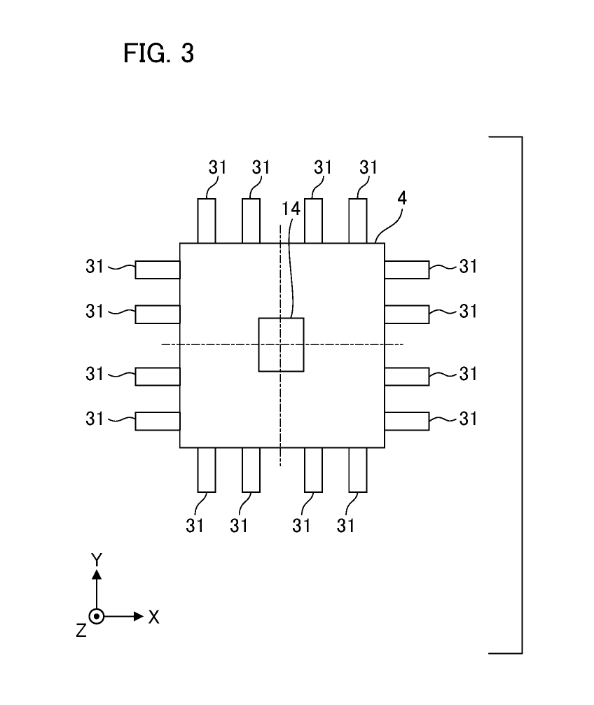

Here, a detailed description will be given of the correction methods for the shape of the pattern portion 14 and the pattern shape formed on the substrate 2 using the mold shape correction mechanism 10 and the substrate heating mechanism 11, which are performed in step S109 and step S110. FIG. 3 illustrates a configuration of the mold shape correction mechanism 10. A place at which the pattern portion 14 is reduced at a certain magnification by using all of the actuators 31 arranged in each of the side surfaces of the mold 4 is defined as a reference. It is possible to correct the shape of the pattern portion 14 to any shape by pushing and pulling the actuators 31 based on the reference.

The substrate heating mechanism 11 can heat only a part of the region on the substrate 2, and changes the pattern formation region 23 into a desired shape or a desired size by heating the pattern formation region 23 on the substrate 2. The substrate heating mechanism 11 includes a heating light source 33 that irradiates an irradiation light 32, the light adjustment device 34 that adjusts the amount of irradiation of the irradiation light 32, and a dichroic mirror 26 that regulates an optical path such that the adjusted light 35 directs toward the surface of the substrate 2.

The irradiation light 32 of the heating light source 33 is desirably a light having wavelengths in which imprint material 3, which is an ultraviolet-curing resin, is not photosensitive (cured), for example, a light that has wavelengths within a wavelength band of 400 nm to 2,000 nm. In particular, from the point of view of heating efficiency, the irradiation light 32 of the heating light source 33 is desirably a light in a wavelength band of 500 nm to 800 nm. Additionally, the irradiation light 32 of the heating light source 33 is not limited to a light having wavelengths that is within the above wavelength band, and it is possible to use, for example, the ultraviolet rays in the wavelength band that is less photosensitive to the imprint material 3, among ultraviolet rays in the wavelength band of 200 nm to 400 nm that is photosensitive to the imprint material 3.

In order to form a desired irradiation amount distribution at least in the plane region of the pattern formation region 23, the light adjustment device 34 can irradiate only a light having a specific wavelength, of the irradiation light 32, toward the surface of the substrate 2. As this light adjustment device 34, for example, a liquid crystal device can be employed, in which a plurality of liquid crystal elements is arranged on a light transmitting surface, voltages for the plurality of liquid crystal elements are individually adjusted, and accordingly, the irradiation amount distribution can be changed. Alternatively, as the light adjustment device 34, a digital mirror device (digital micro-mirror device) can be employed, in which a plurality of mirror elements is arranged in a light reflecting surface, the surface directions of the mirror elements are individually adjusted, and accordingly, the irradiation amount distribution can be changed. The light adjustment device 34 can change an amount of irradiation depending on the location in the plane region of the pattern formation region 23.

The heating light source 33 and the light adjustment device 34 described above are disposed in the imprint apparatus 1 so as not to interfere with the optical path of the ultraviolet rays 5 irradiated from the light irradiation unit 6 in curing the imprint material 3. In the present embodiment, the heating light source 33 and the light adjustment device 34 are configured to irradiate the adjusted light 35 from the side surfaces in the X-axis direction at the upper of the mold 4. The adjusted light 35 advances along the XY plane, is reflected at the dichroic mirror 26, is transmitted through the mold 4, and is irradiated to the pattern formation region 23 that is present on the substrate 2. In contrast, the ultraviolet rays 5 irradiated from the light irradiation unit 6 advance along the XY plane, are reflected at the dichroic mirror 13, and are irradiated onto the substrate 2.

As the substrate heating mechanism 11 forms the irradiation amount distribution in the pattern formation region 23 of the substrate 2, the temperature distribution in accordance with the amount of irradiation is formed, and the substrate 2 can be thermally deformed. Since the mold 4 and the substrate 2 are thermally connected via the imprint material 3, the heat of the substrate 2 is transmitted to the mold 4, and the temperature of the pattern formation region 23 of the substrate 2 and the temperature of the pattern portion 14 of the mold 4 are approximately the same. Here, quartz is used for the material of the substrate 2 in the present embodiment, and a material which has the high transmittance of ultraviolet rays and the difference thermal expansion coefficient from that of the quartz of the substrate 2 is used for the material of the mold 4. For example, the mold 4 is produced by a low thermal expansion glass. While the thermal expansion coefficient of the quartz is 5.1e⁻⁷ [/K], the thermal expansion coefficient of the low thermal expansion glass is 1.0e⁻⁸ [/K] or less. Accordingly, the low thermal expansion glass is used for the material of the mold 4, and thareby the shape of the substrate 2 can be relatively deformed with respect to the mold 4 due to the differences in the thermal expansion coefficient between the mold 4 and the substrate 2, even if the mold 4 and the substrate 2 are the same temperature.

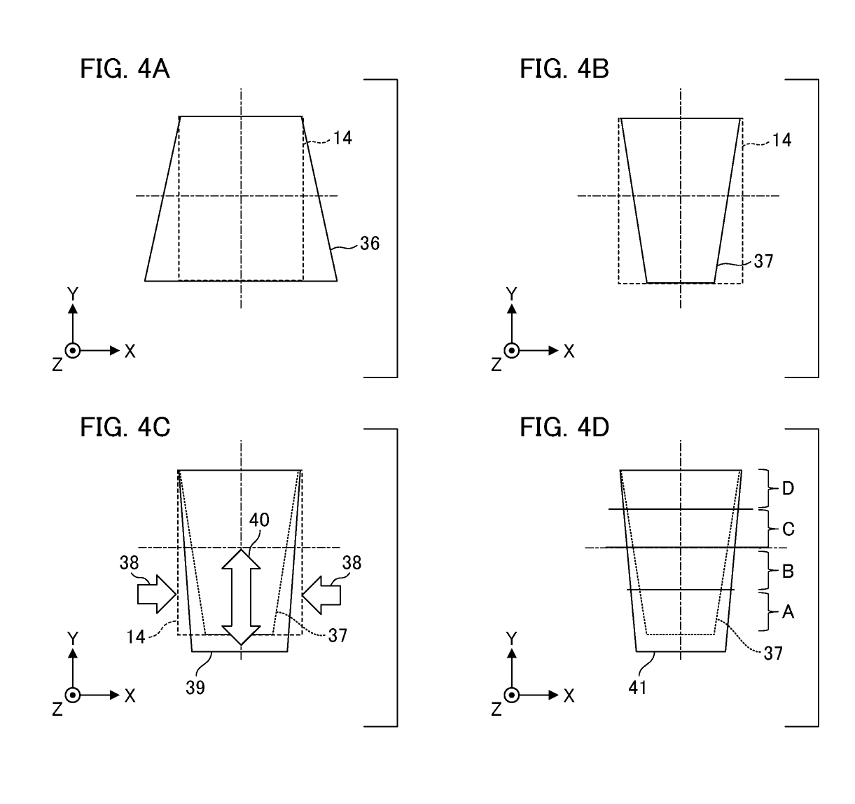

FIGS. 4A to 4D illustrate a correction example by the mold shape correction mechanism 10 and the substrate heating mechanism 11. For example, there is a case in which a difference occurs between the flatness of the mold and the quartz substrate, and the flatness of the holding surface that holds the mold and the quartz substrate. As shown in FIG. 4A, when the imprint of the rectangular pattern portion 14 is performed on the substrate 2, it is assumed that a pattern-on-substrate 36 that is deformed into a trapezoid is formed on the substrate 2 due to an imprint condition and the flatness of the substrate 2 and the substrate holding unit 19. Based on the difference between the pattern portion 14 and the pattern-on-substrate 36, a target shape 37 that corrects the pattern portion 14 can be obtained as shown in FIG. 4B. Based on this target shape 37, the pattern portion 14 is deformed, the imprint is performed on the substrate 2, and the shape difference between the pattern portion 14 and the pattern-on-substrate 36 can be reduced. Here, in a case that the pattern portion 14 is intended to be deformed into the target shape 37 by using only the mold shape correction mechanism 10, a force is applied in the direction of arrows 38 shown in FIG. 4C by the actuators 31 disposed on the four sides of the mold 4. The pattern portion 14 becomes a shape 39. Although the pattern portion 14 approaches the target shape 37, a new deformation occurs in the direction of the arrows 40 perpendicular to the compression direction of the arrow 38 due to the Poisson's ratio effect.

Here, in order to reduce the influence of deformation due to the Poisson's ratio effect upon performing an imprint, the substrate 2 is deformed so as to fit the shape 39 of the pattern portion 14 by using the substrate heating mechanism 11. The substrate heating mechanism 11 forms a temperature distribution in which a region A is the highest in temperature in the regions A to D shown in FIG. 4D, and the temperature decreases in the order of B, C, and D. The uneven temperature distribution in the regions A to D is provided by adjusting the illuminance distribution of the adjusted light 35 from the substrate heating mechanism 11. This method causes the shape of the substrate 2 to be thermally deformed into a substrate target shape 41. The shape 39 obtained by deforming the pattern portion 14 by using the mold shape correction mechanism 10 matches the shape of the substrate target shape 41 obtained by deforming the substrate 2 by using the substrate heating mechanism 11, and the pattern portion 14 can correctly be transferred to the substrate 2.

In the present embodiment, although a low thermal expansion glass is used for the material of the mold 4, quartz may be used for the material of the mold 4, and a low thermal expansion glass may be used for the material of the substrate 2. In this case, if the pattern formation region 23 is heated, the shape of the mold 4 can relatively be deformed with respect to the substrate 2. In a case that the mold 4 is deformed by heat, the substrate 2 may be configured so as to be deformed by a force by the actuators and the like. Additionally, in the present embodiment, although the correction example in the case where the pattern-on-substrate 36 is a trapezoid is described, the present invention is nod limited thereto, and the pattern-on-substrate 36 can appropriately be corrected in accordance with a magnification, and the shape such as rhombus, arcuate, barrel, or bobbin-winding.

Additionally, although the present embodiment provides four regions, A to D forming the temperature distribution, the present invention is not limited thereto with reference to the region division, and it is preferable to divide the regions in accordance with the shape of the pattern-on-substrate 36. Additionally, although the target shape 37 is divided to the regions A to D in the Y direction, the target shape 37 can be divided in the X direction, or the inside of the target shape 37 can be divided into a grid pattern, and accordingly, a temperature distribution may be formed. As described above, it is possible to improve the accuracy of superposition of the mold and the substrate by using heat and utilizing the difference in the thermal expansion coefficient between the mold and the substrate. Therefore, it is possible to provide a mold replicating method that can replicate a mold with a high accuracy.

### Second Embodiment

Next, a description will be given of a mold replicating method in a second embodiment of the present invention. In the mold replicating method of the present embodiment, in order to make thermal expansion coefficients between the substrate 2 and the mold 4 different, micro particles such as metal micro particles of a few nanometers order are dispersed in the quartz of the substrate 2. The irradiation light 32 irradiated from the heating light source 33 of the substrate heating mechanism 11 is preferably a light in wavelength band of 400 nm to 2,000 nm, in which the imprint material 3, which is an ultraviolet-curing resin, is not photosensitive. Moreover, from the viewpoint of heating efficiency, the irradiation light 32 is preferably a light in a wavelength band of 500 nm to 800 nm. Thus, the micro particles are more desirably the ones having a peak of the absorption spectrum of light from 400 nm to 800 nm. In the present embodiment, as an example of the micro particles, silver that has a peak of the absorption spectrum of the light from 400 nm to 500 nm is used. If the substrate heating mechanism 11 irradiates the illumination light 32 for heating onto the substrate 2, in which the silver micro particles are dispersed, the substrate 2 absorbs the light more than the mold 4 to increase a calorific value, as the silver has the peak of the absorption spectrum from 400 nm to 500 nm. Consequently, it is possible to relatively deform the substrate 2 with respect to the mold 4 by dispersing the silver micro particles in the substrate 2.

Additionally, even if a replica mold replicated with the substrate 2, in which the silver micro particles are dispersed is used as a mold to perform the normal imprint, the wavelength band of the ultraviolet rays (200 nm to 400 nm) are out of the peak of the absorption spectrum of the silver. Accordingly, the ultraviolet rays are transmitted without being absorbed by the quartz replica mold in which the silver micro particles are dispersed, and the imprint material 3 can be cured. In the present embodiment, although an example in which the silver particles of a several nanometers order are dispersed in the quartz of the substrate 2 is described, the present invention is not limited thereto. The amount of deformation due to the heat generated by the absorption of the light can be adjusted depending on the type of the micro particles, the shape, the size and the dispersion density of the micro particles to be dispersed in the substrate 2.

Additionally, in the present embodiment, although the metal micro particles are dispersed in the quartz of the substrate 2, the metal micro particles may be dispersed in the quartz of the mold 4 without dispersing the metal particles in the substrate 2 made of the quartz. In this case, when the pattern formation region 23 is heated, it is possible to relatively deform the mold 4 with respect to the substrate 2. As described above, a difference can be caused in the thermal expansion coefficient between the mold and the substrate by mixing the metal micro particles to either the mold or the substrate, and the accuracy of the superposition of the mold and the substrate can be improved with heat by utilizing this difference. Therefore, it is possible to provide a mold replicating method that can replicate a mold with a high accuracy.

### Third Embodiment

Next, a description will be given of a mold replicating method of a third embodiment of the present invention. In the mold replicating method of the present embodiment, a surface that faces the substrate holding unit 19 of the substrate 2 is covered with a thin film. Even if a material of the substrate 2 is quartz that is the same as that of the mold 4, the thermal expansion coefficient of the thin film that covers a part of the substrate 2 is different from the mold 4, and thus, the thermal expansion coefficient of the substrate 2 also differs from the mold 4. The thin film is preferably a metal film such as aluminum, titanium, or the like. While the thermal expansion coefficient of the quartz, which is a material of the mold 4, is 5.1e⁻⁷ [/K], the thermal expansion coefficient of the aluminum film is 2.3e⁻³ [/K], and the thermal expansion coefficient of the titanium film is 8.6e⁻⁶ [/K]. Accordingly, even if the mold 4 and the substrate 2 become the same temperatures upon forming a temperature distribution by the substrate heating mechanism 11, a difference occurs in the thermal expansion coefficient between the mold 4 and the substrate 2 by covering the substrate 2 with a metal film, and it is possible to relatively deform the substrate 2 with respect to the mold 4.

An amount of deformation due to the thermal expansion can be adjusted by a metal type of the metal film, a thickness of the thin film covering the substrate 2, and a region covered with the thin film. Additionally, as the metal film does not transmit a light, the metal film may be removed in an etching process after completing the pattern formation on the substrate 2 in a case where a replica mold replicated by the substrate 2 is used as a mold. As described above, a difference can be caused in the thermal expansion coefficient between the mold and the substrate by covering a part of the substrate of the thin film, and the accuracy of superposition of the mold and the substrate can be improved with heat by utilizing the difference. Therefore, it is possible to provide a mold replicating method that can replicate a mold with a highly accuracy.

### Fourth Embodiment

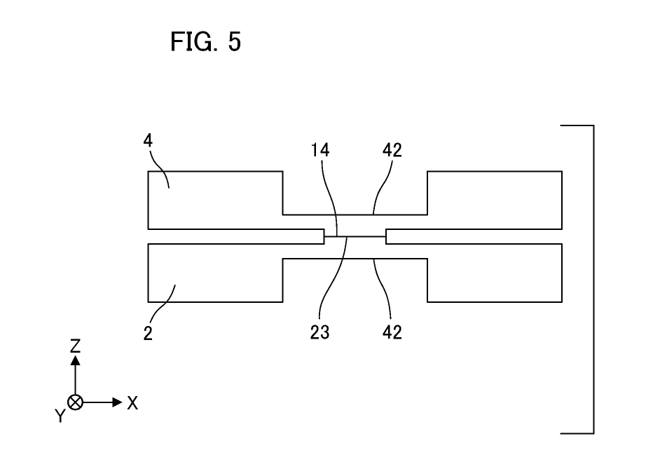

Next, a description will be given of a mold replicating method in a fourth embodiment of the present invention. FIG. 5 illustrates a state of the mold 4 and the substrate 2 of the present embodiment viewed from a side view. In the mold replicating method of the present embodiment,

a cavity 42 (concave portion) having a certain depth is formed in a surface opposite to a convex-concave pattern formed on the mold 4 (surface at the mold holding mechanism 7 side). A configuration is used in which a light transmission member 18 (for example, a quartz plate) is disposed that makes a space obtained by the cavity 42 formed on this mold 4 and a part of the opening region 17 an enclosed space, and a space pressure in the opening region 17 and the cavity 42 can be adjusted by the pressure adjustment device (not illustrated). The pressure adjustment device, for example, sets the pressure in the space higher than that in the outside of the space upon contacting the mold 4 and the imprint material 3 on the substrate 2, and accordingly, the pattern portion 14 can be convexly deflected toward the substrate 2, and can contact the imprint material 3 with the pattern portion 14 from the center.

Similarly, it may be possible to form the cavity 42 (concave portion) having a certain depth in a surface opposite to the pattern formation region 23 formed on the substrate 2 (a surface at the substrate holding unit 19 side). The pattern formation region 23 can be convexly deflected toward the mold 4 by adjusting a pressure in the space in the cavity 42 by the pressure adjustment device (not illustrated).

Thus, even if the cavities 42 are formed in the substrate 2 and the mold 4, the mold replicating method that can replicate the mold with a high accuracy can be provided by using the mold shape correction mechanism 10 and the substrate heating mechanism 11 described above. It is contemplated that a manner of change in the surface of the mold and the substrate differs in response to the shape of the mold 4 and the substrate 2 (presence or absence of the cavity) upon performing the shape correction of the pattern portion 14 and the pattern on the substrate 2. In such a case, it is possible to change an amount of irradiation for the pattern formation region 23 for each shape of the mold 4 and the substrate 2 with respect to a correction amount of the shape. Additionally, if it is desired that the thin film is formed on the mold 4 or the substrate 2 as the third embodiment, the thin film may be provided in the inside where the cavity 42 is formed.

### (Embodiment of Article Manufacturing Method)

A method for manufacturing a device (semiconductor integrated circuit element, liquid display element, or the like) as an article may include a step of forming a pattern on a substrate (wafer, glass plate, film-like substrate, or the like) using the imprint apparatus described above. Furthermore, the manufacturing method may include a step of etching the substrate on which a pattern has been formed. Additionally, the manufacturing method includes a step of forming a pattern on the substrate (wafer, glass plate, film-like substrate, or the like) by using the mold (replica mold) replicated in accordance with the mold replicating method described above. When other articles such as a patterned medium (storage medium), an optical element, or the like are manufactured, the manufacturing method may include another step of treating (processing) the substrate on which a pattern has been formed instead of the etching step. The article manufacturing method of the present embodiment has an advantage, as compared with a conventional method, in at least one of performance, quality, productivity and production cost of an article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2016-010534, filed Jan. 22, 2016, and Japanese Patent Application No. 2016-249830, filed Dec. 22, 2016, which are hereby incorporated by reference herein in their entirety.

What is claimed is:

1. A mold replicating method for replicating a master mold by forming a pattern of the master mold on a substrate, the method comprising:
obtaining information related to a shape difference between a pattern region of the master mold and a pattern region of the substrate; and
deforming a relative shape of the pattern region of the master mold and the pattern region of the substrate by applying heat based on the information,
wherein the master mold and the substrate differ in an amount of deformation with respect to the heat applied.

2. The mold replicating method according to claim 1, wherein the master mold and the substrate have thermal expansion coefficients that differ from each other.

3. The mold replicating method according to claim 1, wherein one of the master mold and the substrate is made of quartz and the other is made of a low thermal expansion glass.

4. The mold replicating method according to claim 1, wherein micro particles are dispersed in one of the master mold and the substrate.

5. The mold replicating method according to claim 4, wherein the micro particles have the peak of an absorption spectrum of a light that is in the range of 400 nm to 800 nm.

6. The mold replicating method according to claim 5, wherein the micro particles are silver micro particles.

7. The mold replicating method according to claim 1, wherein a film covers a surface with which the substrate and a substrate holding unit are in contact, and a thermal expansion coefficient of the film is larger than a thermal expansion coefficient of the master mold.

8. The mold replicating method according to claim 7, wherein the film is aluminum or titanium.

9. The mold replicating method according to claim 1, wherein, in deforming, the relative shape is deformed by adjusting an illuminance distribution of a light for performing the heating and by providing a non-uniform temperature distribution due to the heating.

10. An imprint apparatus for contacting an imprint material and a substrate of a replica mold on which a pattern of a master mold is formed, to transfer a pattern formed on the replica mold to the imprint material,
wherein the master mold is replicated as the replica mold by forming the pattern of the master mold on the substrate in accordance with a method comprising:
obtaining information related to a shape difference between a pattern region of the master mold and a pattern region of the substrate; and
deforming a relative shape of the pattern region of the master mold and the pattern region of the substrate by applying heat based on the information,
wherein the master mold and the substrate differ in an amount of deformation with respect to the heat applied.

11. An article manufacturing method comprising:
forming a pattern of a resin on a substrate using a replica mold which is manufactured under a mold replicating method for replicating a master mold by forming a pattern of the master mold on a substrate for the replica mold; and
processing the substrate on which the pattern has been formed in the forming
wherein the mold replicating method comprises:
obtaining information related to a shape difference between a pattern region of the master mold and a pattern region of the substrate; and
deforming a relative shape of the pattern region of the master mold and the pattern region of the substrate by applying heat based on the information,
wherein the master mold and the substrate differ in an amount of deformation with respect to the heat applied.
